(19) United States
(12) Patent Application Publication
(10) Pub. No.: US 2024/0373589 A1
(43) Pub. Date: Nov. 7, 2024

(54) FLOW MANAGEMENT IN A HEAT-GENERATING DEVICE

(71) Applicant: Microsoft Technology Licensing, LLC, Redmond, WA (US)

(72) Inventor: Ruslan NAGIMOV, Snohomish, WA (US)

(21) Appl. No.: 18/321,342

(22) Filed: May 22, 2023

Related U.S. Application Data
(60) Provisional application No. 63/499,526, filed on May 2, 2023.

(51) Int. Cl. H05K 7/20

(52) U.S. Cl. CPC H05K 7/20281; H05K 7/20272; H05K 7/20763; H05K 7/20836

(57) ABSTRACT

A device cooling system includes a first flow adjuster positioned in-line with a first channel and a second flow adjuster positioned in-line with a second channel. The first flow adjuster is configurable to selectively adjust a first flow impedance within the first channel and the second flow adjuster is configurable to selectively adjust a second flow impedance within the second channel. The first flow impedance is independently adjustable relative to the second flow impedance.

### CROSS-REFERENCE TO RELATED APPLICATIONS

The present application claims priority to U.S. provisional patent application Ser. No. 63/499,526 entitled “Flow Management in a Heat-Generating Device” and filed on May 2, 2023, which is hereby incorporated by reference for all that it discloses or teaches.

### BACKGROUND

Heat-generating electronic devices often include cooling systems that are either actively controlled or passively controlled. An actively controlled cooling system typically includes one or more fans or coolant pumps that are turned on and off and/or driven at different speeds to alter a volume of coolant flowing through various channels of the electronic device. At data centers, it is common to arrange servers in racks or trays and use a same active cooling source (e.g., the same fan(s) or pump(s)) to flow coolant through a group of servers. In contrast, a passively-controlled cooling system typically does not include a fan or coolant pump and is instead driven by natural conduction and/or convection processes that dissipate heat to a target heat outlet.

### SUMMARY

According to one implementation, a method of coolant flow management within an electronic device includes selectively altering a first flow impedance within a first channel of the electronic device by changing a physical configuration of a first flow adjuster positioned in-line with the first channel and further includes selectively altering a second flow impedance within a second channel of the electronic device by changing a physical configuration of a second flow adjuster positioned in-line with the second channel. The selective altering of the first flow impedance is performed independent of the selective altering of the second flow impedance.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Other implementations are also described and recited herein.

### BRIEF DESCRIPTION OF THE DRAWINGS

FIG. 1 illustrates an example heat-generating device with flow adjusters that are each independently controllable to adjust coolant flow in a respective, localized region of the heat-generating device.

FIG. 2 illustrates an example electronic device with independently-controllable flow adjusters that each provide local temperature control within a different region of an electronic device.

FIG. 3 illustrates an example electronic device with flow adjusters that are actively-controlled to provide adjustable flow impedance in a localized area of the electronic device.

FIG. 4 illustrates an example group of servers in a shared physical configuration that each include one or more actively-controlled flow adjusters that provide adjustable flow impedance in localized area(s) of the corresponding server.

FIG. 5 illustrates an example of a flow adjuster that presents an adjustable flow impedance that is passively controlled via thermal actuation rather than active control signals.

FIG. 6 illustrates another example of a flow adjuster that is passively controlled via thermal actuation rather than actively with control signals.

FIG. 7 illustrates example operations for managing coolant flow within a heat-generating device.

FIG. 8 illustrates an example schematic of a processing device suitable for implementing aspects of the disclosed technology.

### DETAILED DESCRIPTION

One disadvantage to both passive and active cooling systems is that current architectures support substantially static flow patterns throughout the various channels of a device without supporting local variabilities in flow rates for more granular temperature control. For example, a passive cooling system typically includes a fixed distribution of heat sinks and coolant flow channels that results in a fixed (static) pattern of coolant flow throughout the corresponding device. Although active cooling systems do provide flow control at a global level (e.g., by varying fan or pump speed), active cooling systems are also static in the sense that a same general coolant flow pattern is typically observed at each different globally-selected flow rate. For example, the overall rate of coolant flow may be increased or decreased but changes in the flow uniformly affect all channels that receive the coolant flow.

This foregoing is disadvantageous because it does not account for the variable heat dissipation patterns and variable thermal resistances of individual components that are observed in typical device, particularly processing devices. For example, CPU-heavy workloads generate heat preferentially in CPUs while memory-heavy workloads generate heat preferentially in memory components. Thus, the distribution of localized heat can change within a processing device depending upon the type of workload that the processing device is executed. Consequently, an ideal cooling system is dynamically configurable to provide adjustable localized temperature control in different regions of the device depending on current heat distribution patterns and component thermal resistances. Existing cooling systems do not support this capability.

The disclosed technology is directed to a cooling system that includes multiple “local” flow adjusters that each introduce an adjustable impedance to a corresponding coolant channel or group of coolant channels. Each flow adjuster can be actuated independent of each other flow adjuster to vary the adjustable impedance in the corresponding coolant channel or channel group. Consequently, coolant flow can be locally controlled to influence local temperature at various locations within a heat-generating device.

The flow adjusters of the disclosed cooling system provide several advantages over existing device cooling systems. First, the ability to independently control coolant flow (and therefore temperature) in different regions of an electronic device can allow a device cooling system to dynamically “react” to the heat generated by a given workload and provide individualized flow adjustments to better remove heat from local hot spots within the device that vary in position depending on workload.

It is also worth noting that temperature cycling has the potential to harm electronic components and there are therefore some performance advantages, such as increased reliability and longevity of lifetime to be realized by maintaining an electronic component within a select temperature range that is optimal for the component's performance as compared to maintaining the component at a temperature range that deemed “safe” for all electronic components within the device.

The ability to dynamically adjust flow at multiple independently-controllable locations within an electronic device also makes it possible to engineer a uniform cooling system suitable for implementation in different types of processing devices that traditionally have different cooling needs. Notably, a more powerful processor may require a more cooling (e.g., a higher average rate of coolant flow) than a less powerful processor. In a server implementing the herein-disclosed universal cooling system architecture, it is possible to replace (e.g., hot-swap) a less powerful processor with a more powerful processor without performing physical modifications to the cooling system within the server due to the fact that coolant flow can be independently modified in the vicinity of the new processor without substantially changing localized coolant flow in other regions of the same server.

Likewise, the ability to dynamically adjust coolant flow at multiple independently-controllable flow adjusters makes it possible to use servers that traditionally have different cooling needs in a same chassis or rack. In data centers that utilize immersion cooling, it is common to attach a group of servers to a tray and then to submerge the entire tray in a cooling tank that is filled with coolant and that includes one or more pumps to circulate the coolant throughout the tank. Although the coolant pump(s) can be controlled to increase or decrease the flow of coolant circulating in the tank, this design typically results in a uniform distribution and flow of the coolant at each individual server. In such a system, a server with higher cooling needs is traditionally incompatible with an immersion tank having a flow level optimized for a group of servers with lower cooling needs. However, systems implementing the herein-disclosed “universal cooling system” with indecently-actuatable flow adjusters are configurable to providing different and individually-tailored coolant flows through different servers arranged in a same rack, chassis, and/or submersion tank because coolant flow can be dynamically controlled at multiple locations within each individual server as well as at the global level for entire the group of servers (e.g., by controller fan or pump power).

The above-described uniform cooling system that supports same-rack/chassis location of servers with different cooling needs reduces the complexity of data center operations and maintenance and also potentially reduces wide-scale design and manufacturing costs. In some implementations, power savings can also be realized by controlling flow at a finer granularity. For example, a flow of coolant can be increased to a hot spot within an individual server to cool the hot spot without increasing the fan speed or coolant pump power to an entire group of servers in a same chassis or rack (notably, a more power-intensive solution).

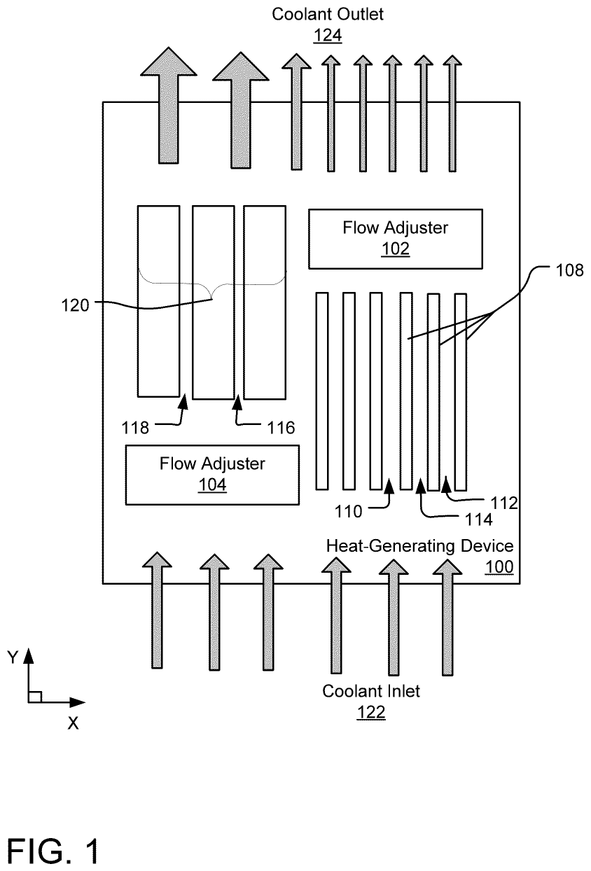

FIG. 1 illustrates an example heat-generating device 100 with flow adjusters 102, 104 that are each independently controllable to adjust coolant flow in a respective, localized region of the heat-generating device 100. Each of the flow adjusters 102, 104 presents an adjustable flow impedance that is in-line with a coolant channel or a group of coolant channels that direct current through a corresponding bank of electronic components. For example, the flow adjuster 102 is in-line with a first channel group (e.g., including channels 110, 112, 114) that direct coolant vertically, in the illustrated Y-direction, in between components of first component bank 108 (e.g., a group of heat-generating components). Likewise, the flow adjuster 104 is in-line with a second channel group (e.g., including channels 116, 118) that also direct coolant vertically and in between components of a second component bank 120.

Each of the flow adjusters 102, 104 presents an adjustable impedance that selectively varies the impedance in-line with current flow throughout the corresponding channel group. When the adjustable impedance is increased, a flow of coolant through the corresponding channel group decreases, locally increasing temperature. Similarly, when the adjustable impedance is decreased, the flow of coolant through the localized channel group increases, locally decreasing temperature.

The flow adjusters 102 and 104 are independently and dynamically adjustable, meaning that the different flow adjusters may introduce the same or different impedance to each respective channel group and the relative variations in the impedances introduced may vary at different times, such as depending on localized temperature conditions and/or the potentially variable thermal resistances observed within the first component bank 108 and the second component bank 120. For simplicity, the heat-generating device 100 illustrates two flow adjusters; however, any number of flow adjusters may be included in a given device cooling system.

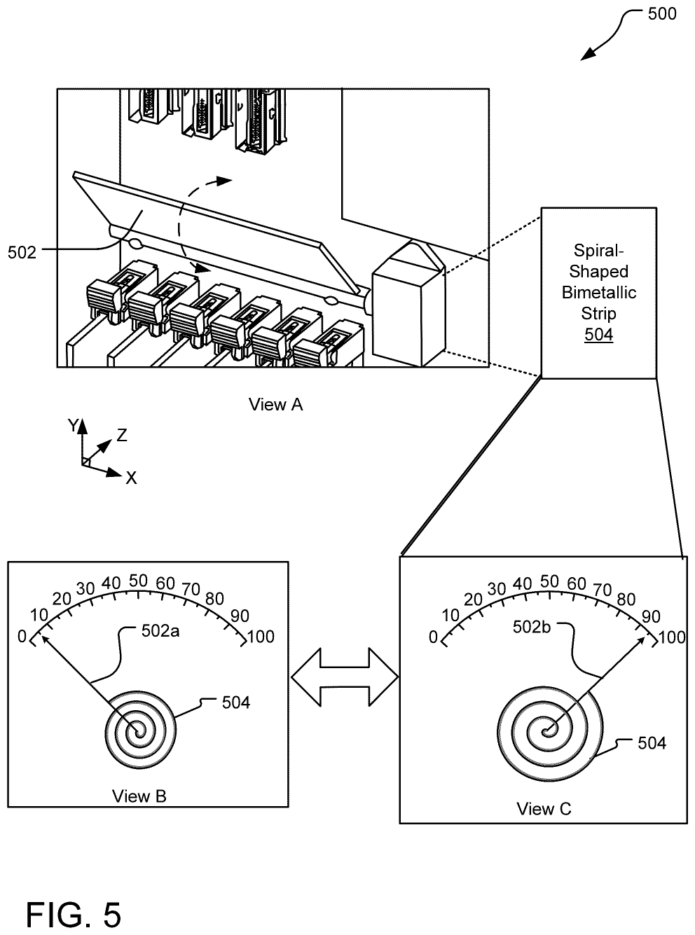

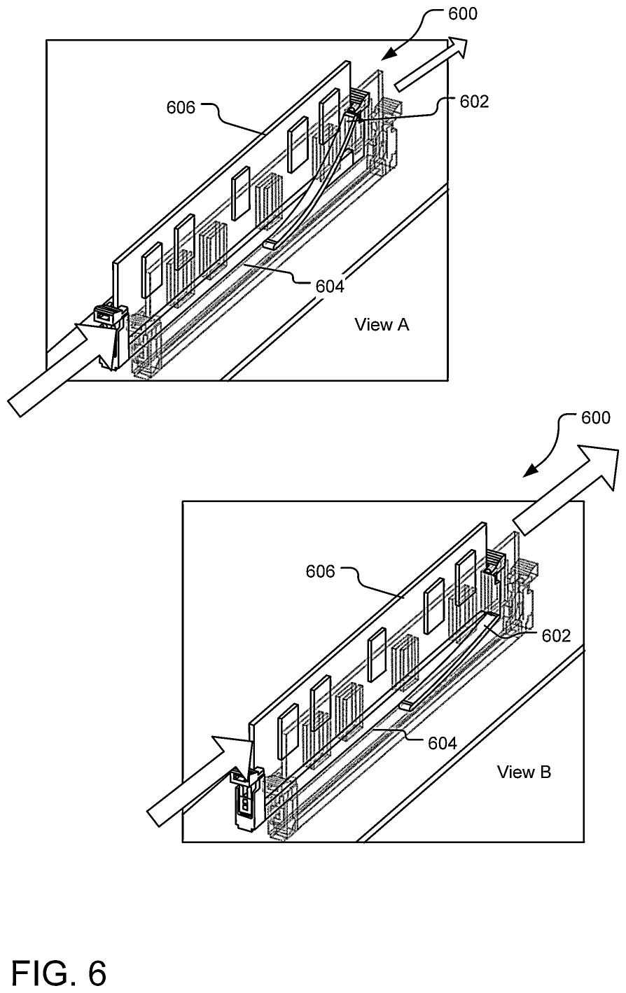

In some implementations, the heat-generating device 100 is an active cooling system driving by one or more coolant fans or pumps, such as a fan located proximal to a coolant inlet 122 or a coolant outlet 124 or a pump located within a coolant immersion thank that the heat-generating device 100 is submerged in. In other implementations, the heat-generating device 100 includes an entirely passive cooling system. As used herein, “passive cooling” implies that cooling is achieved without the use of control signals, such as control signals to vary the speed of fans or pumps. Passive cooling components may, in some cases, be thermally actuated as is discussed further with respect to FIG. 5-6.

In the example shown, coolant flow is substantially uniform across the heat-generating device at the coolant inlet 122. Due to increased local temperature in the region of the second component bank 120 relative to the region of the first component bank 108, the impedance introduced by the flow adjuster 104 is dynamically adjusted to present a local flow impedance that is lower than a local flow impedance provided by the flow adjuster 102. Consequently, a flow of coolant downstream of the first component bank 108 is reduced in flow rate relative to a flow of the coolant downstream of the second component bank 120. Effectively, these differences in local flow rates allow for coolant to carry more heat away from the second component bank 120 than from the first component bank 108 over a same period.

In the event that the first component bank 108 begins generating more heat, the adjustable impedance provided by the flow adjuster 102 can be decreased by a proportional amount (e.g., increasing flow rate) so as to maintain the first component bank 108 at same temperature or within a target temperature range continuously throughout nominal device operations. Likewise, the adjustable impedance provided by the flow adjuster 104 can similarly be increased or decreased to allow for higher or lower flow rates within the region including the component bank 120, so as to maintain the second component bank 120 at a same temperature or within a target temperature target temperature range continuously throughout nominal device operations.

In different implementations, the flow adjusters 102, 104 include different physical characteristics and/or actuation mechanisms. In some implementations, the adjustable impedance of the flow adjusters 102, 104 is actively controlled by a control signal generated in response to detected temperature changes. In other implementations, the adjustable impedance of the flow adjusters 102, 104 is passively controlled (e.g., without control signal actuation), such as by thermal expansion and/or contraction of component(s) within the flow adjusters 102, 104.

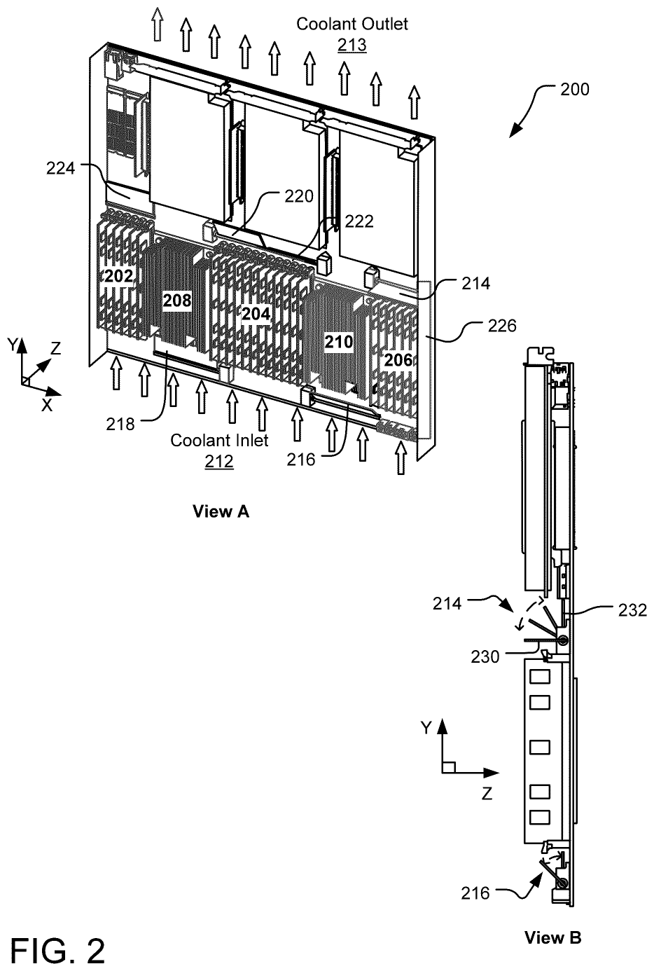

FIG. 2 illustrates an example electronic device 200 with independently-controllable flow adjusters (e.g., flow adjusters 214, 216) that each provide local temperature control by locally providing an adjustable flow impedance that changes a flow of coolant in a corresponding region of the electronic device. By example, the electronic device 200 is shown to be a main server board of the type that may be arranged in a rack with multiple other server boards that share aspects of a cooling system such as by circulating the same coolant (e.g., air or liquid coolant), sharing one or more fans, or being jointly submerged in a tank of liquid coolant. In other implementations, the electronic device 200 is not a server board but instead is any type of device with heat-generating components.

The electronic device 200 includes multiple banks of heat-generating components that are, by example, shown to include memory banks 202, 204, 206 and CPU banks 208 and 210. In one implementation, each of the memory banks 202, 204, 206 includes multiple dual in-line memory modules (DIMMs), also commonly called a RAM sticks, which comprises a series of dynamic random-access memory integrated circuits. Each of the CPU banks 208 and 210 includes one or more processors that may be single core or multiple core. Within each individual memory bank (e.g., 202, 204, and 206) the different individual memory components are separated by channels through which a coolant, such as air or liquid coolant, can flow when in route between a cooling inlet 212 and coolant outlet 213. Likewise, the individual different processors within each of the CPU banks 208 and 210 are also separated by through-channels along which the coolant flows between the coolant inlet 212 and the coolant outlet 213.

In the illustrated example, one or more different flow adjusters (e.g., one of flow adjusters 214, 216, 218, 220, 222, and 224) are positioned in-line with coolant flow through each different bank of the heat-generating components. For example, the flow adjuster 214 is in-line with a first group of channels carrying coolant through the memory bank 206 and the flow adjuster 216 is in-line with a second group of channels carrying coolant through the CPU bank 210. Each of the flow adjusters 214, 216, 218, 220, 222, and 224 provides local temperature control proximal to the corresponding most-proximal bank of the electronic components by altering an adjustable flow impedance that serves to slow or increase a rate of coolant flow through the associated component bank (e.g., the memory bank 206 or the CPU bank 210).

In different implementations, the flow adjusters 214, 216, 218, 220, 222, and 224 assume different physical forms. In general, however, the term “flow adjuster” is intended to refer to a component that is selectably actuatable (e.g., response to a control signal or local conditions such as a temperature) to change in position (e.g., changing in configuration, orientation, size, or shape) and to thereby vary an impedance encountered by coolant flowing through the flow adjuster. This variable impedance that affects flow rate is also referred to herein as “flow impedance.”

By example, the flow adjusters 214, 216, 218, 220, 222, and 224 are shown to be baffles (e.g., planar flanges) that rotate about a first hinged axis and thereby vary in angular orientation relative to coolant flow.

For clarity of concept, View B of FIG. 2 illustrates a side perspective view of the electronic device 200 with an edge portion 226 of the server board omitted to reveal underlying components including the flow adjusters 214 and 216. Each of the flow adjusters 214 and 216 rotates about a hinged axis for selective configuration at each position in a range of positions generally indicated by dotted arrows in View B. When the flow adjuster 214 is actuated to a first position 230 with the baffle substantially perpendicular to coolant flow through the memory bank 206 (e.g., with the planar portion of the baffle parallel to the Z-axis), high impedance is presented within the region of the memory bank 206. This significantly impedes the flow of coolant in this localized area and thereby slows the rate at which heat is removed from this area relative to the relative rate of heat removal achieved at other positions of the baffle. When the flow adjuster 214 is actuated to a second position 232 with the baffle substantially parallel to coolant flow (e.g., parallel to the Y-axis), minimal impedance is presented within the localized region of the memory bank 206, and substantially all of the adjustable flow impedance is removed from the corresponding flow channels. As the baffle is actuated from the first position 230 and toward the second position 232, the corresponding flow impedance gradually decreases as the angular separation decreases between the baffle and the coolant flow.

In other implementations, the flow adjusters 214, 216, 218, 220, 222, and 224 assume forms other than that of a rotatable baffle such as that of an adjustable gate valve (e.g., a gate that opens and closes to obstruct the flow of coolant), a bellow valve (e.g., like an accordion tube perpendicular the coolant flow that supports greater throughput when in an extended position as compared to a contracted position), planar components with holes that slide relative to one another to alter hole-to-hole overlap and thereby alter flow throughput, as well as any other flow adjustment mechanism readily known in the art.

Since the flow adjusters are independently controllable, each flow adjuster may be “open” by a different degree at any given point in time. At the point in time shown in FIG. 2, the flow adjuster 214 is 0% open (maximum impedance), flow adjuster 216 is 50% open, the flow adjuster 222 is 33% open, the flow adjuster 220 is 67% open, and the flow adjusters 218 and 224 are 100% open (minimum impedance).

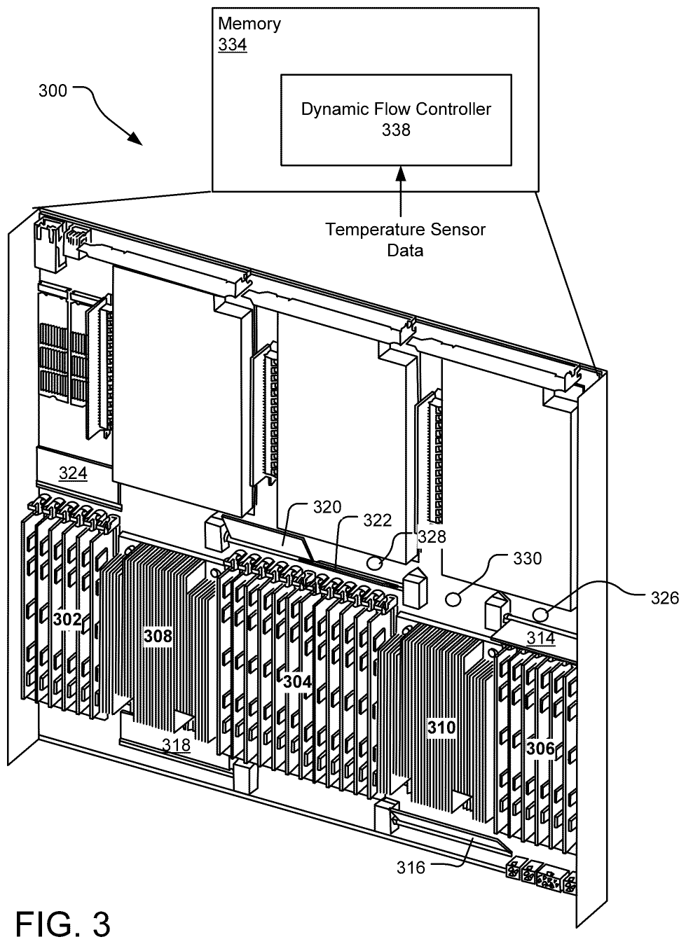

FIG. 3 illustrates an example electronic device 300 with flow adjusters (e.g., flow adjusters 314, 316,318, 320, and 324 that are actively-controlled to provide adjustable flow impedance in a localized area of the electronic device. By example, the electronic device 300 is shown to be identical to that of FIG. 2; however, FIG. 3 additionally illustrates temperature sensors (e.g., sensors 326, 328, 330) that collect temperature data. Additionally, FIG. 3 illustrates a dynamic flow controller 338 that is stored in memory 334 of the electronic device 300, such as within one of multiple memory banks 302, 304, 306. The dynamic flow controller 338 is executed by a processor, such as a processor in either of multiple CPU banks 308, 310 of the electronic device 300. The dynamic flow controller 338 is configured to generate control signals to control the adjustable impedance of each of the flow adjusters 314, 316, 318, 320, and 324 based on temperature measurements collected by the temperature sensors within the electronic device 300.

In FIG. 3, each of the temperature sensors 326, 328, and 330 are each positioned proximal to and down-stream of a corresponding heat generating device (e.g., 306, 304 and 310, respectively). Here, it can be assumed that temperature sensors are also positioned downstream of the heat generating devices 302 and 308 but these sensors are not visible in the present configuration since they are each obscured by the rotatable baffle of the corresponding flow adjuster. In various different implementations, the temperature sensors may be distributed throughout the device in different arrangements.

The dynamic flow controller 338 employs a closed-loop algorithm such as a proportional (P), proportional-integral (PI), proportional-integral-derivative (PID), or model predictive control (MPC) algorithm, to actively control the orientation (and thereby flow impedance affecting local temperature) of each of the flow adjusters 314, 316, 318, 320, and 324 independent of the other flow adjusters in the electronic device 300. In different implementations, the selected algorithm is driven by different considerations to satisfy different cooling objectives.

In one implementation, the dynamic flow controller 338 controls each flow adjuster to ensure that a component bank proximal to the flow adjuster is maintained at a constant temperature or within a select temperature range. For example, the dynamic flow controller 338 receives one or more temperature readings associated with each different component bank (e.g., CPU bank 210, memory bank 206) and, based on the temperature reading(s), generates control signals to increase or decrease the local flow impedance (and thereby decrease or increase coolant flow) through the component bank.

Notably, temperature cycling can be damaging to electronics, and different electronic components often have different optimal operational temperatures that are known to improve reliability and/or lifetime of the component. The herein-described flow adjusters can be utilized to ensure that each individual component bank is maintained at a corresponding select temperature that is known to be optimal for the components within that component bank (e.g., as compared to maintaining the bank at a conservative temperature that is known to be safe for all components in the electronic device 300).

According to another approach, the dynamic flow controller 338 controls each individual flow adjuster in the electronic device 300 to ensure that a component bank proximal to the flow adjuster is maintained at a temperature that is at or below an overall maximum temperature deemed safe for that specific component bank. This approach is similar to that described above except that the component banks are intentionally maintained at the “hot” end of the safe temperature range rather than the “optimal” (e.g., best reliability/lifetime) temperature. Advantageously, this approach mitigates wear and tear on the flow adjusters 314, 316, 318, 320, and 324 by significantly reducing or minimizing the number and frequency of flow impedance adjustments that are implemented. At the same time, this approach ensures each individual component bank is protected from thermal damage due to the fact that the operational temperature of each bank is still within the “safe” zone for that individual component. Notably, this approach can save on overall power consumed as compared to common cooling system approaches that maintain the entire electronic device 300 in a conservative temperature range that is deemed safe for the most thermally-sensitive components within the device.

In still another implementation, the dynamic flow controller 338 controls each flow adjuster to ensure that a temperature downstream of each of the flow adjusters and component banks (e.g., near a coolant outlet) is very high or maximized, meaning that the coolant flow exits at near the highest allowed temperature. When this approach is employed, the coolant exiting the electronic device is warm enough to be reused and recycled as thermal energy elsewhere in a data center.

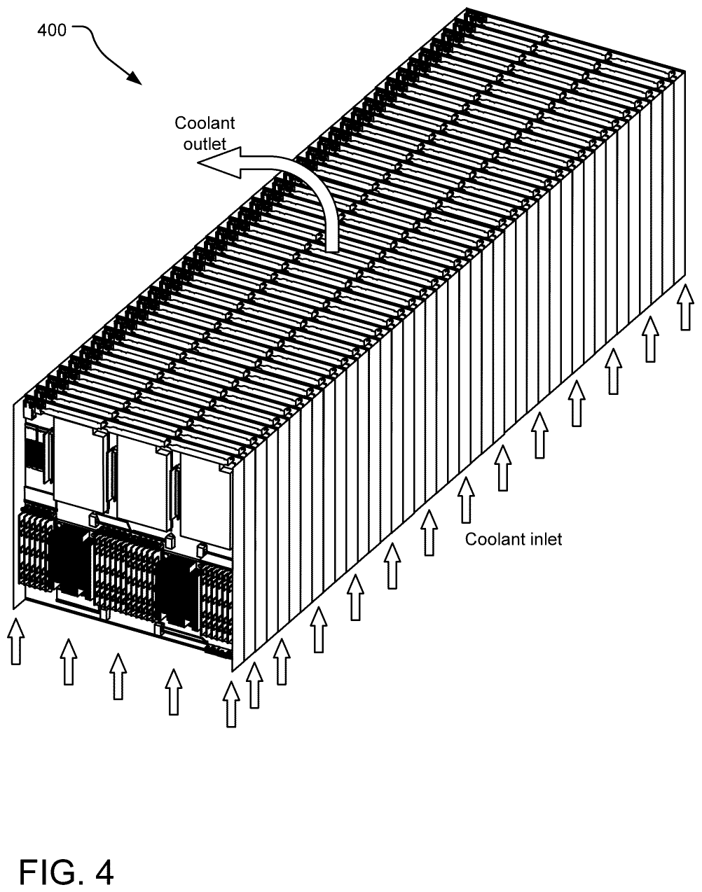

FIG. 4 illustrates an example group of servers 400 (e.g., servers 402, 404, 406) in a shared physical configuration (e.g., a shelf or tray) that each include one or more actively-controlled flow adjusters that provide adjustable flow impedance in localized area(s) of the corresponding server. In FIG. 4, an active cooling source is shared by all servers in the group 400. In this example, the active cooling source is a pump within a coolant tank. The servers 400 are submerged within the cooling tank and the pump circulates coolant through the group of servers 400. In a common configuration, the cooling tank includes a single pump that that drives liquid coolant from the bottom of the cooling tank to the top of the cooling tank (e.g., also known as a single-phase immersion cooling tank), as generally indicated by the arrows in FIG. 4.

In other implementations, the active cooling source shared by the group of servers 400 is a fan instead of a pump. For example, the servers 400 are arranged in a same rack or chassis proximal to the fan.

In either of the above implementations (e.g., active cooling by pump or fan), the servers 400 each execute an instance of the dynamic flow controller that is discussed above with respect to FIG. 3. The dynamic flow controller of each server controls the flow impedance introduced by flow adjuster(s) of the server according to adjustment rules geared toward satisfying a blade, rack, or chassis-level cooling objective, such as to keep all servers operational without taking any servers offline for maintenance. If, for example, a single server malfunctions and begins to overheat, coolant flow through active cooling source can be increased by increasing it speed, the dynamic flow controllers of all other servers in the group 400 can independently adjust their own internal flow adjuster(s) to increase internal flow impedance (and thereby maintain required levels of internal cooling), resulting in increased coolant flow rate only through affected overheating server, keeping the overheating server online without substantial operational impact to the other servers. In some implementations, the speed of the coolant pump may be adjusted to further this goal.

Take, for example, the scenario where an individual one of the servers in the cooling tank has a CPU that goes “bad” due to the failing of a thermal interface between the CPU and the heat sink. Generally, this type of scenario requires removal of the server with the bad CPU (the “overheating server”) for maintenance or replacement. However, the need to service the overheating server can be postponed or eliminated completely by (1) increasing power of the coolant pump while concurrently (2) controlling the flow adjusters of the overheating server to minimize flow impedance; and (3) controlling the flow adjusters of the “good” servers to increase flow impedance by an amount that substantially offsets (e.g., cancels out) the increase in flow rate attributable to the increased pump power.

If, in the above scenario, the overheating server detects that a current temperature within a first channel is indicative of an overheat condition while an associated flow adjuster is already adjusted to provide a minimum available flow impedance within the first channel, the server may then transmit a request for an increase in power of the active cooling source to control electronics coupled to the active cooling source. In response, the control electronics increase the active cooling source power (e.g., the pump power within the cooling tank), effectively increasing a rate of coolant flowing through the first channel of the overheating server (as well as through all other servers and their respective channels in the group). Here, the increased coolant flow suffices to cool the overheating server.

In this same scenario, other servers in the group 400 detect the power increase of the active cooling source and independently take action to control their own respective flow adjusters to prevent associated local temperatures from dropping below respective target ranges in response to the increase in coolant flow rate. If, for example, a server detects an increase in the power of the active cooling source at a time when all channels and/or components within the server are within associated target temperature ranges, the server can respond by automatically adjusting the physical configuration of each of its respective flow adjusters to increase flow impedance by an amount within each corresponding channel such that a resulting coolant flow rate through each of the channels is substantially identical (e.g., +/−5%) to an initial coolant flow rate through the channel prior to the power increase of the active coolant source.

In the above scenario, coolant flow is effectively increased through the bad server by increasing the power of the active cooling source and the coolant flow rate through the other servers in the server group 400 is substantially unchanged after local flow impedance adjustments are performed.

In still another use scenario employing the same cooling technique, a select server in a rack or cooling tank is intentionally driven to a higher-than-nominal CPU usage (“overclocked”) such as to support a cloud tenant leasing the processing resources that demands a temporary increase in compute power. Commonly, this scenario is addressed by provisioning an additional server for use by the cloud tenant. However, in some cases, efficiencies can be realized by provisioning fewer overall resources to maximize the number of tenants that can be supported by a set number of servers. By increasing power of the rack-level cooling mechanism (e.g., fan or pump) and controlling the flow adjusters of the overclocked server to decrease flow impedance temporarily, the overclocked server can be operated at a safe temperature despite the higher-than-nominal usage. At the same time, average flow rates through the remaining servers can remain substantially unchanged if the flow impedance is locally increased within those servers by a corresponding amount that offsets the increased flow rate at the coolant intake attributable to the higher pump power in the tank.

Notably, the above-described scenarios that perform flow adjustments to achieve tray, rack, or chassis-level cooling objectives may, in some implementations, rely upon server-to-server communications and/or communications with control electronics coupled to the active cooling source (e.g., coolant pump or fan). For example, the “bad” server communicates with control electronics (e.g., rack-level controller or pump-control electronics) to request an increase in the pump power, and the other servers are notified of these communications, such as over a same communication bus and/or directly from the control electronics. Consequently, the other “good” servers can respond by locally increasing flow impedance, as described above.

FIG. 5 illustrates an example of a flow adjuster 500 that is passively controlled via thermal actuation rather than actively with control signals. The flow adjuster 500 includes a baffle 502 that rotates about an axis to alter an angular separation between a planar edge of the baffle and a stream of coolant. In contrast to the actively-driven flow adjusters discussed elsewhere herein, the flow adjuster 500 is driven by a spiral-shaped bimetallic strip 504 that expands and contracts with changes in local temperature.

A bimetallic strip typically includes two sheets of different types of materials with different thermal coefficients of expansion. Depending on properties of these materials and how they are oriented relative to one another, either heating or cooling causes the strip to bend. The greater the difference in the coefficients of thermal expansion of the materials included within the bimetallic strip, the greater the degree of bending. In one common approach, a bimetallic strip is formed by layering a sheet of copper or brass below a sheet of steel. This arrangement results in a strip that bends when heated and the degree of this bend (e.g., the angle achieved per constant unit of heat applied) is tunable by varying the length of the bimetallic strip and the thicknesses of the two different material sheets.

A concept of operation for using the spiral-shaped bimetallic strip 504 to actuate a flow adjuster is illustrated with respect to View B and View C of FIG. 5. Here, lines 502a and 502b are used to represent a position of the baffle 502 at different positions and at different temperatures. For example, the baffle 502 is attached to the end of the spiral-shaped strip and shifts in position with the thermal deformation of the spiral-shaped bimetallic strip 504. As the spiral-shaped bimetallic strip 504 is heated, the baffle 502 shifts from a first position 502a to a second position 502b, thereby locally varying the flow impedance. In the illustrated example, local flow impedance is decreased (facilitating an increase in flow rate) when the local temperature is increased and the local flow impedance is increased (decreasing flow rate) when the local temperature is decreased.

In View A of FIG. 5, the spiral-shaped bimetallic strip 504 is shown as being encased in a housing positioned in substantial alignment with the flow adjuster 500 along an axis (e.g., the x-axis) perpendicular to a flow of coolant (e.g., flowing along the y-axis). In another implementation, the spiral-shaped bimetallic strip 504 is upstream or downstream within the flow of current relative to the flow adjuster 500. For example, the flow adjuster 500 and the spiral-shaped bimetallic strip 504 are substantially aligned along the y-axis, in-line with the flow of current. This upstream/downstream arrangement may be beneficial in that the spiral-shaped bimetallic strip 504 is, in such configuration, subjected to temperature variations more similar to those observed within a nearby component bank that is associated with and cooled by the flow adjuster 500. Thus, the local temperature is more tightly controlled as compared to implementations where the spiral-shaped bimetallic strip 504 is positioned as shown.

FIG. 6 illustrates another example of a flow adjuster 600 that is passively controlled via thermal actuation rather than actively with control signals. Here, the flow adjuster 600 includes a bimetallic strip 602 positioned in a channel between two components 604, 606. For example, the two components are DIMMs in a memory bank, two adjacent fins of a CPU heat sink, or any other pair of identical or non-identical components. In one implementation, an electronic device includes multiple flow adjusters with characteristics the same or similar to the flow adjuster 600 independently controlling local coolant flow and temperature in different regions of the electronic device.

In one implementation, the bimetallic strip 602 is designed to bend as shown in FIG. 6 View A when local temperature drops below a threshold. When the local temperature increases above the threshold, the bimetallic strip 602 straightens out, as shown in FIG. 6 View B. The bent configuration of the bimetallic strip 602 in View A is associated with a higher flow impedance within the channel between the heat-generating components 604, 606 than a flow impedance associated with a substantially planar (unbent) configuration of the bimetallic strip 602 that is shown in View B. When the bimetallic strip 602 is bent as in View A, coolant flow through the channel is significantly impeded. This concept is generally illustrated shown by the relative sizes of arrows corresponding to channel input and channel output, respectively. This reduced coolant flow rate is conducive to increasing the local temperature. When, in contrast, the bimetallic strip 602 is straight as in View B, coolant flow through the channel is substantially unobstructed, increasing or maximizing flow rate and heat dissipation from the channel. Consequently, the local temperature decreases as compared to the configuration of View A.

In other implementations, other types of thermally actuated flow adjusters may be employed in a manner consistent with the implementations described herein.

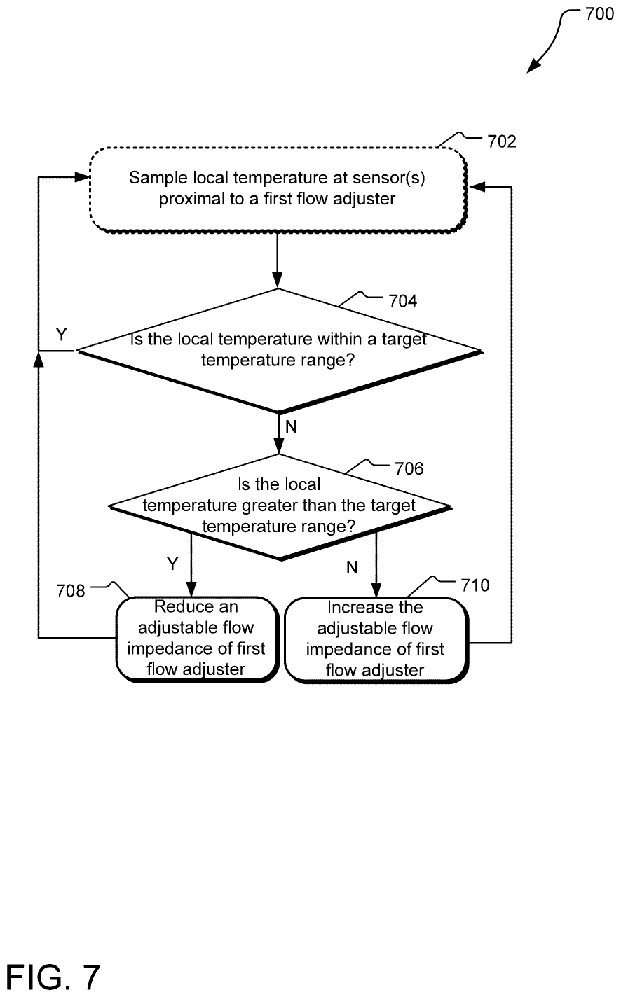

FIG. 7 illustrates example operations 700 for managing coolant flow within a heat-generating device, such as a server. In one implementation, the heat-generating device includes multiple independently-adjustable flow adjusters, and the operations 700 are performed with respect to each different flow adjuster (e.g., concurrently or sequentially) in the heat-generating device. Each of the flow adjusters introduces an adjustable flow impedance to a corresponding channel or group of channels (e.g., through a bank of components) within the heat-generating device.

In the illustration flow of the operations 700, a sampling operation 702 samples local temperature at one or more sensors proximal to a first flow adjuster in the heat generating device. For example, the local temperature is sampled at a sampling point that is within a channel in-line with the first flow adjuster or at a component that is proximal to the flow adjuster. The sampling point is, in various implementations, either upstream or downstream of the first flow adjuster.

Notably, FIG. 7 illustrates the sampling operation 702 in dotted lines to indicate that temperature sampling is not required to practice the disclosed technology. For instance, a number of implementations implement flow adjusters that are thermally-actuated rather than actively-controlled (e.g., by firmware-generated control signals). In these implementations, the flow management operations 700 are performed automatically by a thermally-actuated flow adjuster when local temperature rises above or drops below a target temperature that the thermally-actuated flow adjuster is tuned to respond to.

A determining operation 704 determine whether the local temperature proximal to the first flow adjuster is within a target temperature range associated with the flow adjuster and/or one or more components physically proximal to the flow adjuster. Notably, each flow adjuster may be associated with a different target temperature range. For example, different components within the server may have different optimal temperature ranges (e.g., ranges identified by a manufacturer as ideal for maximizing performance, component lifetime, or optimizing other criteria), and the flow adjusters associated with each of these components can therefore be controlled to maintain local temperature near the component within the target range selected for the component. As discussed elsewhere herein, different devices (e.g., servers) may also have different target operational temperature ranges and/or cooling needs and the flow adjusters can therefore be selectively controlled differently within different devices to provide variable degrees of cooling.

If the determining operation 704 determines that the local temperature proximal to the first flow adjuster is within the target temperature range, no adjustment action is taken and the operations proceed back to the beginning of the flow (e.g., to the sampling operation 702, corresponding to a next temperature sampling of the sensor(s) proximal to the first flow adjuster.

If, however, the local temperature proximal to the first flow adjuster is determined to be external to the target temperature range, another determining operation 706 determines whether the local temperature is greater than the target temperature range. If so, an impedance flow reduction operation 708 reduces flow impedance of the first flow adjuster, such as by a predefined increment or by a select magnitude corresponding to a differential between the sampled local temperature and the target temperature range. For example, the heat-generating device stores a table that associates sampled temperature(s) with different selectable configurations of the flow adjuster, and the table is queried to identify a predefined one of the selectable configurations usable to reduce the flow impedance to most quickly return the local temperature to within the target temperature range.

If the determining operation 706 determines that the local temperature is below (less than a lower bound of) the target temperature range, an impedance flow increase operation 710 increases flow impedance of the first flow adjuster, such as by a predefined increment or by a select magnitude corresponding to a selectable configuration of the flow adjuster stored in a table in association with one or more temperature ranges, as described above.

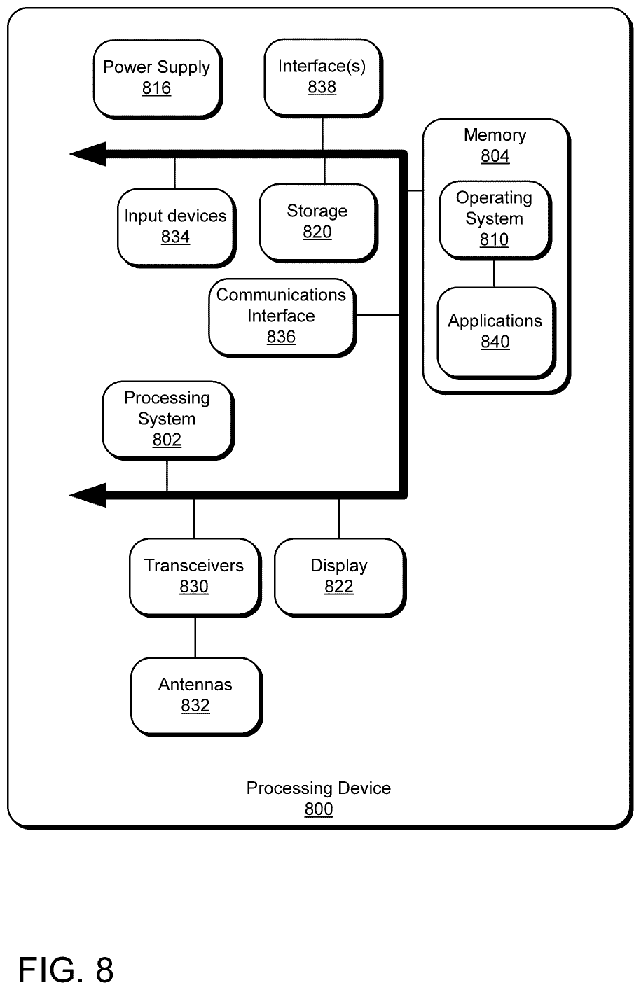

FIG. 8 illustrates an example schematic of a processing device 800 suitable for implementing aspects of the disclosed technology. In one implementation, the processing device 800 includes a cooling system with multiple independently-controllable flow adjusters that each present an adjustable flow impedance that affects a rate of coolant flow through an associated channel group consisting of a single channel or multiple channels that flow through one or more banks of electronic (e.g., heat-generating) components.

The processing device 800 includes a processing system 802, memory device(s) 804, the display 806, and other interfaces 808 (e.g., buttons). The memory device(s) 804 generally includes both volatile memory (e.g., RAM) and non-volatile memory (e.g., flash memory). An operating system 810 may reside in the memory device(s) 804 and be executed by the processing system 802. One or more applications 812, such as the dynamic flow controller 338 of FIG. 3 may be loaded in the memory and executed on the operating system 810 by the processing system 802.

The processing device 800 includes a power supply 816, which is powered by one or more batteries or other power sources and which provides power to other components of the processing device 800. Additionally, the processing device 800 includes one or more communication transceivers 830 and an antenna 832 to provide network connectivity (e.g., a mobile phone network, Wi-Fi®, BlueTooth®). The processing device 800 may be further coupled to various input devices 834 such as a microphone, keyboard, touch display, etc. In an implementation, an installation script generation engine, along with other various applications and other modules and services, are embodied by instructions stored in memory device(s) 804 and/or storage devices 828 and processed by the processing system 802. The memory device(s) 804 may be memory of host device or of an accessory that couples to a host. The installation script generation engine my include a trained multi-layer neural network that is saved in the memory device(s) 804 or saved in memory of one or more other compute devices (e.g., various interconnected processing nodes) that are communicatively coupled to the processing device 800, such as via the internet.

The processing device 800 may include a variety of tangible computer-readable storage media and intangible computer-readable communication signals. Tangible computer-readable storage can be embodied by any available media that can be accessed by the processing device 800 and includes both volatile and nonvolatile storage media, removable and non-removable storage media. Tangible computer-readable storage media excludes intangible and transitory communications signals and includes volatile and nonvolatile, removable and non-removable storage media implemented in any method or technology for storage of information such as computer readable instructions, data structures, program modules or other data. Tangible computer-readable storage media includes, but is not limited to, RAM, ROM, EEPROM, flash memory or other memory technology, CDROM, digital versatile disks (DVD) or other optical disk storage, magnetic cassettes, magnetic tape, magnetic disk storage or other magnetic storage devices, or any other tangible medium which can be used to store the desired information and which can be accessed by the processing device 800. In contrast to tangible computer-readable storage media, intangible computer-readable communication signals may embody computer readable instructions, data structures, program modules or other data resident in a modulated data signal, such as a carrier wave or other signal transport mechanism. The term “modulated data signal” means a signal that has one or more of its characteristics set or changed in such a manner as to encode information in the signal. By way of example, and not limitation, intangible communication signals include wired media such as a wired network or direct-wired connection, and wireless media such as acoustic, RF, infrared and other wireless media.

Some embodiments may comprise an article of manufacture. An article of manufacture may comprise a tangible storage medium to store logic. Examples of a storage medium may include one or more types of computer-readable storage media capable of storing electronic data, including volatile memory or non-volatile memory, removable or non-removable memory, erasable or non-erasable memory, writeable or re-writeable memory, and so forth. Examples of the logic may include various software elements, such as software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. In one implementation, for example, an article of manufacture may store executable computer program instructions that, when executed by a computer, cause the computer to perform methods and/or operations in accordance with the described embodiments. The executable computer program instructions may include any suitable type of code, such as source code, compiled code, interpreted code, executable code, static code, dynamic code, and the like. The executable computer program instructions may be implemented according to a predefined computer language, manner or syntax, for instructing a computer to perform a certain function. The instructions may be implemented using any suitable high-level, low-level, object-oriented, visual, compiled and/or interpreted programming language.

In some aspects, the disclosed technology is implemented in a cooling system in an electronic device. The cooling system includes a first flow adjuster positioned in-line with a first channel in the electronic device and a second flow adjuster positioned in-line with a second channel in the electronic device. The first flow adjuster is configurable to selectively alter a first flow impedance within the first channel, and the second flow adjuster is configurable to selectively alter a second flow impedance within the second channel. The first flow impedance is independently adjustable relative to the second flow impedance.

In an example cooling system of any preceding cooling system, the first flow adjuster dynamically alters the first flow impedance in response to temperature changes within the first channel and the second flow adjuster dynamically alters the second flow impedance in response to temperature changes within the second channel.

In another example cooling system of any preceding cooling system, the first channel directs coolant through a first bank of electronic components and to a coolant outlet and wherein the second channel directs coolant through a second bank of electronic components and to the coolant outlet.

In another example cooling system of any preceding cooling system, the first flow adjuster and the second flow adjuster are actively-controlled components and the cooling system further includes: a dynamic flow controller stored in memory and configured to: receive one or more temperature sensor measurements; and based on the one or more temperature sensor measurements, transmit one or more control signals to selectively adjust the first flow impedance of the first flow adjuster and the second flow impedance of the second flow adjuster.

In another example cooling system of any preceding cooling system, the first flow adjuster is a thermally-actuated component.

In another example cooling system of any preceding cooling system, the first flow adjuster includes a bimetallic strip configured to bend in response to an increase in local temperature.

In another example cooling system of any preceding cooling system, the first flow adjuster includes a baffle configured to rotate about an axis to adjust the first flow impedance.

In another example cooling system of any preceding cooling system, an angular orientation of the baffle is passively controlled by thermal actuation of a spiral-shaped bimetallic strip.

In some aspects, the techniques described herein relate to a method including: selectively altering a first flow impedance within a first channel of an electronic device by changing a physical configuration of a first flow adjuster positioned in-line with the first channel; and selectively altering a second flow impedance within a second channel of the electronic device by changing a physical configuration of a second flow adjuster positioned in-line with the second channel, the first flow impedance being independently adjustable relative to the second flow impedance.

In some aspects, the techniques described herein relate to a method, further including: selectively altering the first flow impedance within the first channel in response to temperature changes detected proximal to the first channel; and selectively altering the second flow impedance within the second channel in response to temperature changes detected proximal to the second channel.

In some aspects, the techniques described herein relate to a method, wherein the first flow adjuster and the second flow adjuster are actively-controlled components and the method further includes: receive a temperature sensor measurement associated with the first channel; and based at least in part on the temperature sensor measurement, generate a control signal effective to change a physical configuration of the first flow adjuster and alter the first flow impedance within the first channel.

In some aspects, the techniques described herein relate to a method, wherein the first flow adjuster is a thermally-actuated component.

In some aspects, the techniques described herein relate to a method, wherein the first flow adjuster includes a bimetallic strip configured to bend in response to an increase in local temperature.

In some aspects, the techniques described herein relate to a method, wherein the first flow adjuster includes a baffle and the first flow impedance is adjusted by rotating the baffle about an axis.

In some aspects, the techniques described herein relate to a method, wherein an angular orientation of the baffle is passively controlled by thermal actuation of a spiral-shaped bimetallic strip.

In some aspects, the techniques described herein relate to a system including: a group of servers physically configured to share an active cooling source, each server in the group of servers including: one or more flow adjusters, each of the one or more flow adjusters being in-line with an associated channel in the server and having an adjustable physical configuration that alters flow impedance within the associated channel; and a dynamic flow controller stored in memory of the server that generates control signals for altering a physical configuration of each of the one or more flow adjusters in the server in response to temperature variations within the server.

In some aspects, the techniques described herein relate to a system, wherein the one or more flow adjusters of a first server in the group are controlled to maintain the first server within a first target temperature range, and wherein the one or more flow adjusters a second server in the group are controlled to maintain the second server within a second target temperature range different from the first target temperature range.

In some aspects, the techniques described herein relate to a system, wherein the control signals adjust the physical configuration of each flow adjuster of the one or more flow adjusters based on a target temperature for the channel in-line with the flow adjuster, the target temperature being different with respect to at least one of: different channels in-line with different flow adjusters in a same server of the group; or different channels in-line with different flow adjusters in different servers of the group.

In some aspects, the techniques described herein relate to a system, wherein the dynamic flow controller of each server is further configured to: determine that a current temperature within a first channel is indicative of an overheat condition; determine that a first flow adjuster in-line with the first channel is already adjusted to provide a minimum-available flow impedance within the first channel; and transmit a request for an increase in power of the active cooling source to control electronics coupled to the active cooling source.

In some aspects, the techniques described herein relate to a system, where the dynamic flow controller of each server is further configured to: determine that a first channel of the server is within a target temperature range, the first channel being in-line with a first flow adjuster of the one or more flow adjusters in the server; detect an increase in power of the active cooling source while the first channel is still within the target temperature range, the increase in power of the active cooling source affecting an increase in an initial coolant flow rate through the first channel; and in response to detecting the increase in power of the active cooling source, automatically alter the physical configuration of the first flow adjuster to increase the flow impedance within the first channel such that a resulting coolant flow rate through the first channel is substantially identical to the initial coolant flow rate through the first channel.

In some aspects, a cooling system disclosed herein includes a means for selectively altering a first flow impedance within a first channel of an electronic device by changing a physical configuration of a first flow adjuster positioned in-line with the first channel. The system further includes a means for selectively altering a second flow impedance within a second channel of the electronic device by changing a physical configuration of a second flow adjuster positioned in-line with the second channel. The first flow impedance is independently adjustable relative to the second flow impedance.

The above specification, examples, and data provide a complete description of the structure and use of exemplary implementations. Since many implementations can be made without departing from the spirit and scope of the claimed invention, the claims hereinafter appended define the invention. Furthermore, structural features of the different examples may be combined in yet another implementation without departing from the recited claims.

What is claimed is:

1. A cooling system in an electronic device, the cooling system comprising:
a first flow adjuster positioned in-line with a first channel in the electronic device, the first flow adjuster being configurable to selectively alter a first flow impedance within the first channel; and
a second flow adjuster positioned in-line with a second channel in the electronic device, the second flow adjuster being configurable to selectively alter a second flow impedance within the second channel, the first flow impedance being independently adjustable relative to the second flow impedance.

2. The cooling system of claim 1, wherein the first flow adjuster dynamically alters the first flow impedance in response to temperature changes within the first channel and the second flow adjuster dynamically alters the second flow impedance in response to temperature changes within the second channel.

3. The cooling system of claim 1, wherein the first channel directs coolant through a first bank of electronic components and to a coolant outlet and wherein the second channel directs coolant through a second bank of electronic components and to the coolant outlet.

4. The cooling system of claim 1, wherein the first flow adjuster and the second flow adjuster are actively-controlled components and the cooling system further comprises:
a dynamic flow controller stored in memory and configured to:
receive one or more temperature sensor measurements; and
based on the one or more temperature sensor measurements, transmit one or more control signals to selectively adjust the first flow impedance of the first flow adjuster and the second flow impedance of the second flow adjuster.

5. The cooling system of claim 1, wherein the first flow adjuster is a thermally-actuated component.

6. The cooling system of claim 1, wherein the first flow adjuster includes a bimetallic strip configured to bend in response to a change in local temperature.

7. The cooling system of claim 1, wherein the first flow adjuster includes a baffle configured to rotate about an axis to adjust the first flow impedance.

8. The cooling system of claim 7, wherein an angular orientation of the baffle is passively controlled by thermal actuation of a spiral-shaped bimetallic strip.

9. A method comprising:
selectively altering a first flow impedance within a first channel of an electronic device by changing a physical configuration of a first flow adjuster positioned in-line with the first channel; and
selectively altering a second flow impedance within a second channel of the electronic device by changing a physical configuration of a second flow adjuster positioned in-line with the second channel, the first flow impedance being independently adjustable relative to the second flow impedance.

10. The method of claim 9, further comprising:
selectively altering the first flow impedance within the first channel in response to temperature changes detected proximal to the first channel; and
selectively altering the second flow impedance within the second channel in response to temperature changes detected proximal to the second channel.

11. The method of claim 9, wherein the first flow adjuster and the second flow adjuster are actively-controlled components and the method further comprises:
receive a temperature sensor measurement associated with the first channel; and
based at least in part on the temperature sensor measurement, generate a control signal effective to change a physical configuration of the first flow adjuster and alter the first flow impedance within the first channel.

12. The method of claim 9, wherein the first flow adjuster is a thermally-actuated component.

13. The method of claim 9, wherein the first flow adjuster includes a bimetallic strip configured to bend in response to a change in local temperature.

14. The method of claim 9, wherein the first flow adjuster includes a baffle and the first flow impedance is adjusted by rotating the baffle about an axis.

15. The method of claim 14, wherein an angular orientation of the baffle is passively controlled by thermal actuation of a spiral-shaped bimetallic strip.

16. A system comprising:
a group of servers physically configured to share an active cooling source, each server in the group of servers including:
one or more flow adjusters, each of the one or more flow adjusters being in-line with an associated channel in the server and having an adjustable physical configuration that alters flow impedance within the associated channel; and
a dynamic flow controller stored in memory of the server that generates control signals for altering a physical configuration of each of the one or more flow adjusters in the server in response to temperature variations within the server.

17. The system of claim 16, wherein the one or more flow adjusters of a first server in the group are controlled to maintain the first server within a first target temperature range, and wherein the one or more flow adjusters of a second server in the group are controlled to maintain the second server within a second target temperature range different from the first target temperature range.

18. The system of claim 16, wherein the control signals adjust the physical configuration of each flow adjuster of the one or more flow adjusters based on a target temperature for the channel in-line with the flow adjuster, the target temperature being different with respect to at least one of:
different channels in-line with different flow adjusters in a same server of the group; or
different channels in-line with different flow adjusters in different servers of the group.

19. The system of claim 16, wherein the dynamic flow controller of each server is further configured to:
determine that a current temperature within a first channel is indicative of an overheat condition;
determine that a first flow adjuster in-line with the first channel is already adjusted to provide a minimum-available flow impedance within the first channel; and
transmit a request for an increase in power of the active cooling source to control electronics coupled to the active cooling source.

20. The system of claim 19, where the dynamic flow controller of each server is further configured to:
determine that a first channel of the server is within a target temperature range, the first channel being in-line with a first flow adjuster of the one or more flow adjusters in the server;
detect an increase in power of the active cooling source while the first channel is still within the target temperature range, the increase in power affecting an increase in an initial coolant flow rate through the first channel; and
in response to detecting the increase in power of the active cooling source, automatically alter the physical configuration of the first flow adjuster to increase the flow impedance within the first channel such that a resulting coolant flow rate through the first channel is substantially identical to the initial coolant flow rate through the first channel.
